(19) United States
(12) Patent Application Publication
(10) Pub. No.: US 2010/0013041 A1
(43) Pub. Date: Jan. 21, 2010

(54) MICROELECTRONIC IMAGER PACKAGES WITH COVERS HAVING NON-PLANAR SURFACE FEATURES

(75) Inventor: Larry D. Bolt, Boise, ID (US)

Correspondence Address: Kramer Levin Naftalis & Frankel LLP, 1177 Avenue of the Americas, New York, NY, 10036, US

(73) Assignee: Micron Technology, Inc., Boise, ID (US)

(21) Appl. No.: 12/173,658

(22) Filed: Jul. 15, 2008

(51) Int. Cl. H01L 31/0203; H01L 21/77

(52) U.S. Cl. 257/443; 438/66; 257/E31.117; 257/E21.598

(57) ABSTRACT

Several embodiments of microelectronic imager packages with covers having non-planar surface features are disclosed herein. One embodiment is directed to a imager package that includes an imager die having a plurality of photo sensors and an enclosure substantially enclosing the imager die. The enclosure has a cover attached to a base with an adhesive. The cover has a transparent central portion superimposed with the photo sensors and a peripheral portion around the central portion. The cover has a non-planar portion in the peripheral portion, and the non-planar portion is configured to increase a bonding strength between the cover and the base.

### TECHNICAL FIELD

The present disclosure is directed to microelectronic imager packages with covers having non-planar surface features for improving structural integrity of the packages and associated methods for making such packages.

### BACKGROUND

Individually packaged microelectronic imagers are widely used today in digital cameras, camcorders, and other imaging equipment. Individual microelectronic imagers are typically sealed in a package having a transparent cover attached to a protective enclosure. One drawback of the foregoing microelectronic imager packages is that the transparent cover may delaminate from the protective enclosure under thermal stress, humidity, and/or a combination of other environmental factors. Such delamination can cause the packages to fail. Accordingly, several improvements for enhancing the structural integrity of the microelectronic imager packages would be desirable.

### BRIEF DESCRIPTION OF THE DRAWINGS

FIG. 1 is a partially schematic cross-sectional view of an microelectronic imager package having a cover with a non-planar surface features in accordance with an embodiment of the disclosure.

FIGS. 2A-D are partially schematic bottom views of the cover of FIG. 1 in accordance with several embodiments of the disclosure.

FIGS. 3A-D are partially schematic cross-sectional views of the cover of FIG. 1 in accordance with several embodiments of the disclosure.

FIG. 4A is a partially schematic bottom view of the cover of FIG. 1 in accordance with another embodiment of the disclosure.

FIGS. 4B-C are partially schematic cross-sectional views of the cover of FIG. 4A in accordance with several embodiments of the disclosure.

FIG. 5 is a schematic diagram of a system that includes one or more microelectronic imager packages in accordance with embodiments of the disclosure.

### DETAILED DESCRIPTION

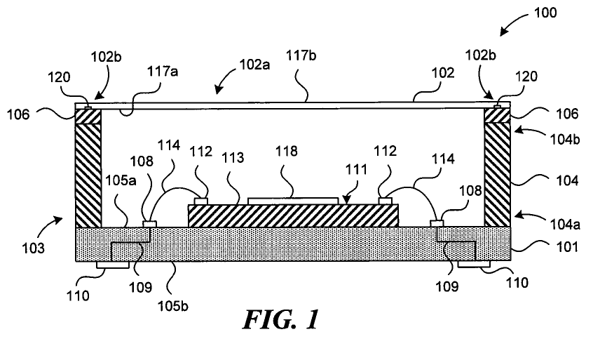

Specific details of several embodiments of the disclosure are described below with reference to microelectronic imager packages and methods for manufacturing microelectronic imager packages from semiconductor components. The semiconductor components are manufactured on semiconductor wafers that can include substrates upon which and/or in which microelectronic devices, micromechanical devices, data storage members, optics, read/write components, and other features are fabricated. For example, SRAM, DRAM (e.g., DDR/SDRAM), flash-memory (e.g., NAND flash-memory), processors, CMOS and/or CCD imagers, and other types of devices can be constructed on semiconductor wafers. Although many of the embodiments are described below with respect to semiconductor devices that have integrated circuits, other embodiments include other types of devices manufactured on other types of substrate. Moreover, several other embodiments can have different configurations, components, or procedures than those described in this section. A person of ordinary skill in the art, therefore, will accordingly understand that the invention can have other embodiments with additional members or without several of the features shown and described below with reference to FIGS. 1-5.

FIG. 1 is a partially schematic cross-sectional view of an microelectronic imager package 100 having a cover 102 with non-planar surface features in accordance with an embodiment of the disclosure. In the illustrated embodiment, the package 100 includes a substrate 101, a semiconductor die 111 carried on the substrate 101, a sidewall 104 around the semiconductor die 111, and the cover 102 attached to the sidewall 104 with an adhesive 106. The substrate 101, the sidewall 104, and the cover 102 form an enclosure 103 that substantially surrounds the semiconductor die 111. Even though the substrate 101 is illustrated in FIG. 1 as independent from the sidewall 104, in certain embodiments, the substrate 101 and the sidewall 104 can be combined into a unitary base.

As illustrated in FIG. 1, in certain embodiments, the substrate 101 can include a plurality of substrate bond sites 108 on a first surface 105a and proximate to the semiconductor die 111, a plurality of ball sites 110 on a second surface 105b, and a plurality of conductive links 109 (e.g., conductive traces) electrically connecting the substrate bond sites 108 to the corresponding ball sites 110. The substrate 101 can be constructed from a polymeric material, glass, ceramics, and/or other suitable nonconductive material. In other embodiments, the substrate 101 can include a lead frame.

The semiconductor die 111 can include at least one CMOS or CCD imager with an array of photo sensors 118 (e.g., photodiodes, photogates, etc.) formed in and/or on an imager substrate 113. The semiconductor die 111 can also include a plurality of die bond sites 112 electrically coupled to internal circuitry (e.g., analog processing circuitry, timing/clock circuitry, analog-to-digital conversion circuitry, and/or other suitable circuitry, not shown) of the semiconductor die 111. In the illustrated embodiment, a plurality of wirebonds 114 electrically couple individual die bond sites 112 to corresponding substrate bond sites 108. In other embodiments, the semiconductor die 111 can also be electrically coupled to the substrate 101 in a flip-chip and/or other desired configuration.

The sidewall 104 can include a first end 104a proximate to the substrate 101 and a second end 104b opposite the first end 104a. The sidewall 104 can be attached to the substrate 101 at the first end 104a with adhesives, mechanical fasteners, and/or other suitable fastening components (not shown). In the illustrated embodiment, the sidewall 104 includes a plate having a generally rectangular cross section between the first and second ends 104a and 104b. In other embodiments, the sidewall 104 can have an L-shaped, a C-shaped, and/or other suitable types of cross section.

The cover 102 can include one or more panes of a polymeric material, glass, quartz, and/or other suitable material transmissive to a desired spectrum of radiation. For example, in the illustrated embodiment, the cover 102 includes a glass plate having a first surface 117a facing the semiconductor die 111 and a second surface 117b opposite the first surface 117a. The cover 102 includes a central portion 102a that is at least partially transparent and generally corresponds to the photo sensors 118 of the semiconductor die 111. The cover 102 also includes a peripheral portion 102b around the central portion 102a. The adhesive 106 is at least partially disposed in the peripheral portion 102b of the cover 102 to attach the cover 102 to the second end 104b of the sidewall 104. In other embodiments, the cover 102 can also include anti-reflective coatings or other suitable optical components on the first and/or second surfaces 117a and 117b.

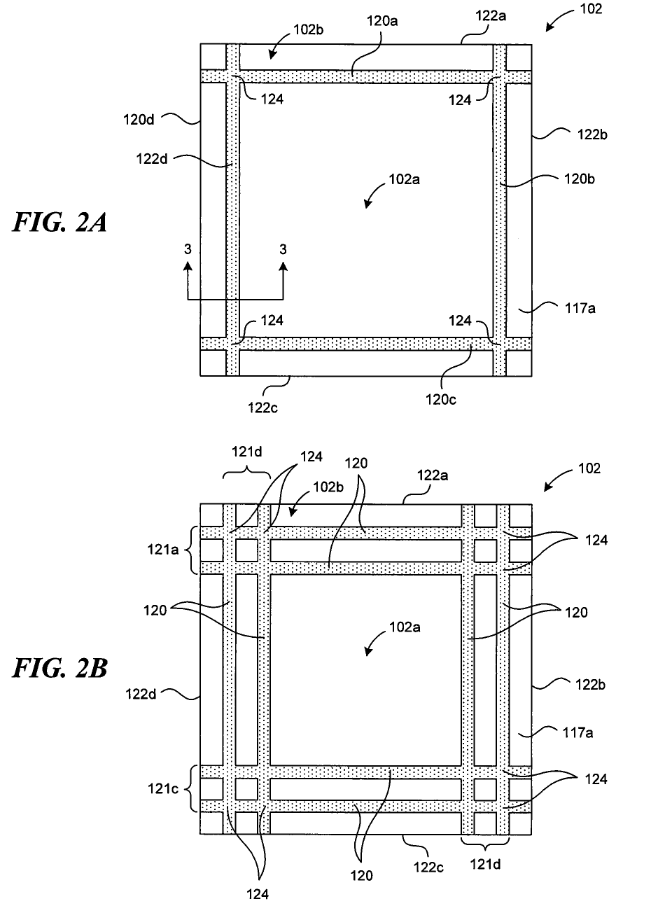

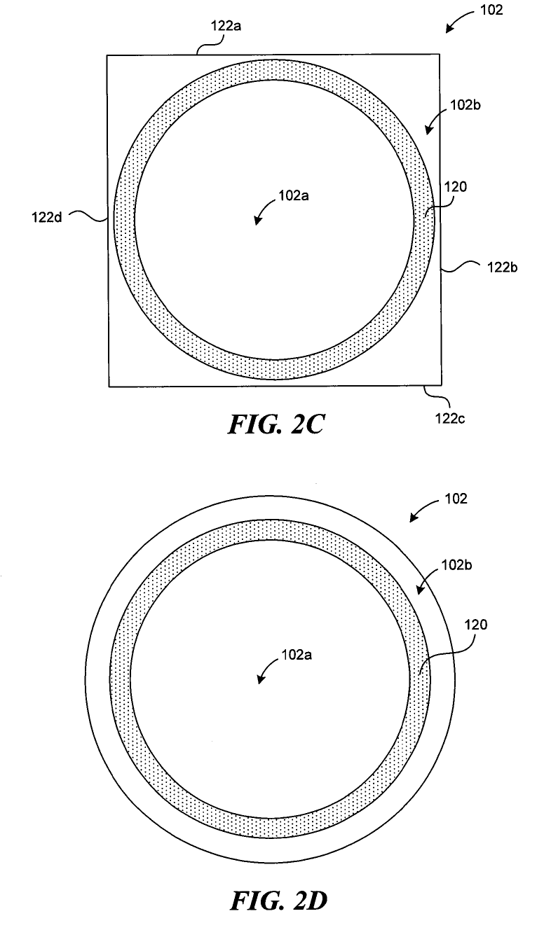

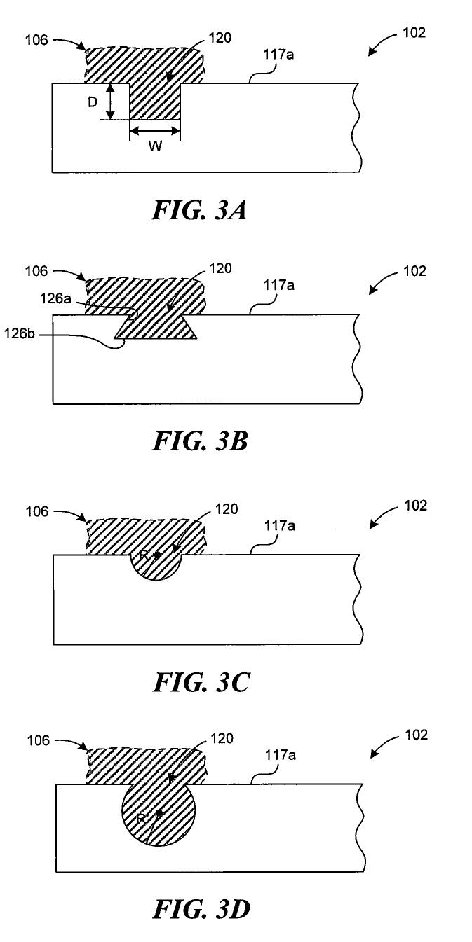

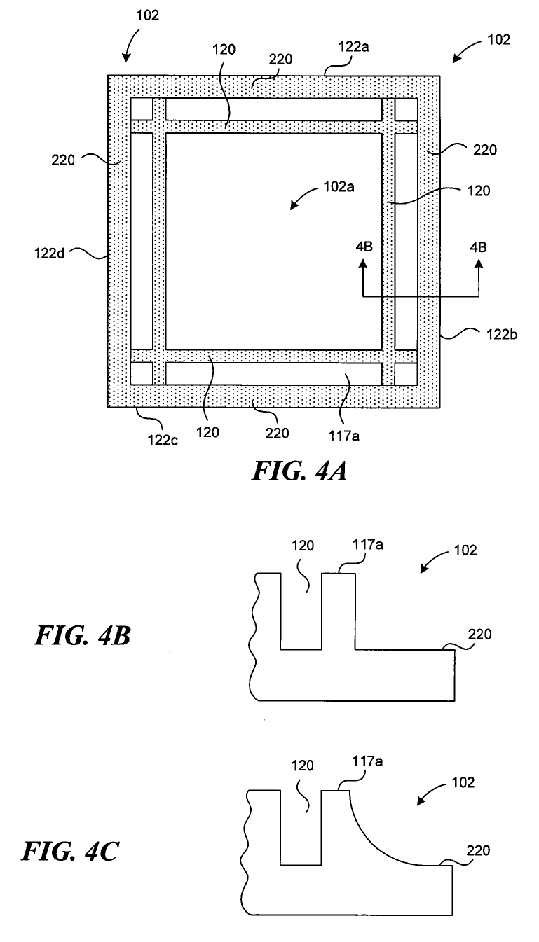

At least the peripheral portion 102b of the cover 102 can be non-planar at the first surface 117a. For example, the cover 102 can include one or more depressions (e.g., channels 120) extending from the first surface 117a into a body portion of the cover 102 in the peripheral portion 102b, as described in more detail below with reference to FIGS. 2A-3D. In another example, the cover 102 can include one or more recesses along its edges, as shown in FIGS. 4A-C. In further embodiments, the cover 102 can include apertures, slits, and/or other non-planar surface features proximate to the first surface 117a. In any of these embodiments, at least a portion of the adhesive 106 is disposed in the non-planar surface features of the cover 102.

FIGS. 2A-D illustrate several examples of the cover 102 having one or more channels in different arrangements. FIGS. 3A-D illustrate several examples of cross-sectional configurations of the channels in FIGS. 2A-D. FIGS. 4A-C illustrate several examples of the cover 102 having a recess along its edges. It is understood, however, that these examples are merely provided for illustration purposes. In other embodiments, the cover 102 can have a combination of one or more of these features. In further embodiments, the cover 102 may have any desired overall shape, surface features, and/or cross sections of the surface features.

FIG. 2A is a partially schematic bottom view of the cover 102 of FIG. 1 in accordance with an embodiment of the disclosure. As shown in FIG. 2A, the cover 102 has a generally rectangular shape with four edges 122 (identified individually as a first edge 122a, a second edge 122b, a third edge 122c, and a fourth edge 122d). The cover 102 can include four linear channels 120 in the peripheral portion 102b of the cover 102 (identified individually as a first channel 120a, a second channel 120b, a third channel 120c, and a fourth channel 120d). The channels 120 individually intersect the corresponding edges 122, and each pair of adjacent channels 120 intersect one another at an intersection 124. In the illustrated embodiment, the channels 120 have generally the same width and are generally parallel to corresponding edges 120. In other embodiments, the channels 120 can have other suitable dimensions and/or arrangements on the first surface 117a of the cover 102. In further embodiments, the channels 120 can be positioned in the peripheral portion 102b of the cover 102 without intersecting with the corresponding edges 122.

In certain embodiments, the cover 102 can also include more than one channel 120 proximate to a corresponding edge 122. As illustrated in FIG. 2B, the cover 102 can include four channel sets 121 (identified individually as a first channel set 121a, a second channel set 121b, a third channel set 121c, and a fourth channel set 121d). Individual channel sets 121 include two channels 120. In other embodiments, individual channel sets can include three, four, or any desired number of channels.

In other embodiments, the cover 102 can include channels in a closed-loop arrangement on the first surface 117a. For example, as illustrated in FIG. 2C, the cover 102 includes a channel 120 that has a generally circular shape in the peripheral portion 102b of the cover 102. In other embodiments, the channel 120 can also have an oval arrangement, a serpentine arrangement, a zigzag arrangement, a square arrangement, and/or other suitable closed-loop arrangement.

In further embodiments, the cover 102 can have other shapes. For example, as illustrated in FIG. 2D, the cover 102 has a generally circular shape and includes the generally circular channel 120 in the peripheral portion 102b of the cover 102. In certain embodiments, the cover 102 and the channel 120 can be generally concentric. In other embodiments, the cover 102 and the channel 120 can be offset from each other. In further embodiments, the cover 102 and/or the channel 120 can have an oval shape, a trapezoidal shape, and/or other desired shapes.

Although FIGS. 2A-D illustrate specific combinations of the shape of the cover 102 and the arrangement of the channels 120, additional embodiments can include other desired combinations. For example, the cover 102 can have a generally circular shape, as illustrated in FIG. 2D, and a plurality of linear channels 120, as illustrated in FIGS. 2A or 2B. In another example, the cover 102 can have a generally rectangular shape as illustrated in FIGS. 2A or 2B, and a plurality of circular channels 120, as illustrated in FIGS. 2C or 2D.

In any of the foregoing embodiments, individual channels 120 can have various cross-sectional configurations and a portion of the adhesive 106 (shown in phantom lines for clarity) can be disposed at least partially in the channels 120. For example, as illustrated in FIG. 3A, the channel 120 can have a generally rectangular cross section extending from the first surface 117a into the cover 102. In certain embodiments, the channel 120 can have a depth D of about 0.05 mm and a width W of about 0.2 mm. In other embodiments, the channel 120 can have other desired dimensions. In another example, as illustrated in FIG. 3B, the channel 120 has a trapezoidal cross section with an opening 126a smaller than a base 126b. The channel 120 can also has a curved cross section. As illustrated in FIG. 3C, the channel 120 has a partially circular cross section with a radius R from a center above or proximate to the first surface 117a. As illustrated in FIG. 3D, the channel 120 can also have a partially circular cross section with a desired radium R′ from a center below the first surface 117a. In other embodiments, the channel 120 can also have an oval cross section, a parabolic cross section, and/or other suitable cross section.

Even though the cover 102 is illustrated above as having the channels 120, in other embodiments, the cover 102 can also include apertures, slits, ledges, and/or other non-planar surface features in addition to or in lieu of the channels 120. For example, as illustrated in FIG. 4A, the cover 102 can include a recess 220 extending along the edges 122 of the cover 102 in addition to the channels 120. The recess 220 can have a generally step-like cross-sectional profile (as illustrated in FIG. 4B), a curved cross-sectional profile (as illustrated in FIG. 4C), or any other desired cross-sectional profiles. In other examples, the channels 120 may be omitted, and the cover 102 can include only the recess 220 with a desired cross-sectional profile.

In certain embodiments, a manufacturing process for making the microelectronic imager package 100 of FIG. 1 can include attaching the semiconductor die 111 to the substrate 101, electrically coupling corresponding die bond sites 112 and substrate bond sites 108 with the wirebonds 114, and attaching the sidewall 104 to the substrate 101. In other embodiments, the substrate 101 and the sidewall 104 can be combined into a base, and thus the attachment of the sidewall 104 to the substrate 101 can be omitted from the manufacturing process.

The manufacturing process can also include forming the non-planar surface features on the cover 102 discussed above with reference to FIGS. 2A-4C. In certain embodiments, forming the surface features can include scribing the cover 102 with a dicing saw (Model No. DFD-650) provided by Disco High Tech America, Inc. of Santa Clara, Calif. to create the channels 120 illustrated in FIG. 3A or other non-planar surface features. In one embodiment, forming the non-planar surface feature with the dicing saw includes programming the dicing saw to form the channels 120 with a depth based on a desired increase in contact surface area with the adhesive 106 compared to a generally planar cover. In another embodiment, forming the surface feature with the dicing saw includes selecting a blade of the dicing saw based on a desired cross-sectional profile of the channels 120. In other embodiments, forming the non-planar surface feature can include forming the channels 120 via plasma etching, chemical etching, and/or other suitable material removal techniques.

After the surface features are formed on the cover 102, the manufacturing process can include disposing the adhesive 106 between the second end 104b of the sidewall 104 and at least a section of the peripheral portion 102b of the cover 102. In one embodiment, disposing the adhesive 106 includes injecting the adhesive 106 in liquid form at least partially into the surface features and onto the first surface 117a of the cover 102, as illustrated in FIGS. 3A-D. In other embodiments, disposing the adhesive 106 can include placing the adhesive 106 in solid form onto the first surface 117a of the cover 102 and subsequently heating the adhesive 106 such that a portion of the adhesive 106 is at least partially in the surface features. In further embodiments, disposing the adhesive 106 can include spraying, printing, and/or otherwise placing the adhesive 106 with suitable techniques. The manufacturing process can then include attaching the cover 102 to the sidewall 104 with the adhesive 106 and optionally curing the adhesive 106.

Referring to FIGS. 1-4C together, the non-planar surface features (e.g., the channels 120 and the recess 220) can improve the bonding strength between the cover 102 and the sidewall 104. Without being bound by theory, it is believed that air bubbles may exist between the adhesive 106 and the cover 102 and/or within the adhesive 106 during manufacturing. When heated in subsequent processing stages, the air bubbles may expand to separate the cover 102 from the sidewall 104 and cause the package 100 to fail. The inventor has recognized that by forming the cover 102 with various non-planar surface features, the contact area between the adhesive 106 and the cover 102 and/or the volume of the adhesive 106 can be increased over conventional techniques. As a result, the adhesive 106 can improve the bonding strength between the cover 102 and the sidewall 104, and thus improving the seal in the package 100.

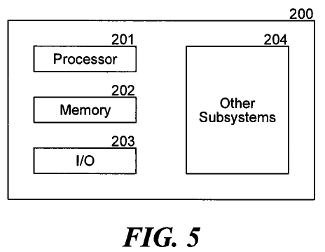

The microelectronic imager package 100 may be incorporated into myriad larger and/or more complex systems 200, a representative one of which is shown schematically in FIG. 5. The system 200 can include a processor 201, a memory 202, input/output devices 203, and/or other subsystems or components 204. Microfeature workpieces (e.g., in the form of microfeature dies and/or combinations of microfeature dies) may be included in any of the components shown in FIG. 5. The resulting system 200 can perform any of a wide variety of computing, processing, storage, sensor, and/or other functions. Accordingly, the representative system 200 can include, without limitation, computers and/or other data processors, for example, desktop computers, laptop computers, Internet appliances, and hand-held devices (e.g., palmtop computers, wearable computers, cellular or mobile phones, multiprocessor systems, processor-based or programmable consumer electronics, network computers, and mini computers). Another representative system 200 can include cameras, light sensors, servers and associated server subsystems, display devices, and/or memory devices. Components of the system 200 may be housed in a single unit or distributed over multiple, interconnected units, e.g., through a communications network. Components can accordingly include local and/or remote memory storage devices and any of a wide variety of computer-readable media, including magnetic or optically readable or removable computer disks.

From the foregoing, it will be appreciated that specific embodiments of the disclosure have been described herein for purposes of illustration, but that various modifications may be made without deviating from the disclosure. For example, many of the elements of one embodiment may be combined with other embodiments in addition to or in lieu of the elements of the other embodiments. Accordingly, the disclosure is not limited except as by the appended claims.

I claim:

1. A microelectronic imager package, comprising:
a substrate;
a semiconductor die carried by the substrate, the semiconductor die having a plurality of photo sensors;
a sidewall positioned around the semiconductor die, the sidewall having a first end proximate to the substrate and a second end opposite the first end;
a cover proximate to the second end of the sidewall, the cover having a central portion superimposed with the photo sensors and a peripheral portion around the central portion and adjacent to the second end of the sidewall, wherein the cover includes a non-planar surface feature in the peripheral portion; and
an adhesive between the second end of the sidewall and the surface of the cover, at least a portion of the adhesive being in the non-planar surface feature of the peripheral portion.

2. The microelectronic imager package of claim 1 wherein the semiconductor die includes a CMOS imager having the plurality of photodiodes, and wherein the cover has a generally rectangular shape, and wherein the non-planar surface feature includes a channel extending along an edge of the cover and having a generally rectangular cross section with a width of about 0.2 mm and a depth of about 0.05 mm, and further wherein a portion of the adhesive is deposed in the channel.

3. The microelectronic device assembly of claim 1 wherein the non-planar surface feature includes at least one of a channel and a recess in the peripheral portion of the cover.

4. The microelectronic device assembly of claim 1 wherein the non-planar surface feature includes a channel in the peripheral portion of the cover, the channel having a curved cross section.

5. The microelectronic device assembly of claim 1 wherein the non-planar surface feature includes a plurality of channels in the peripheral portion of the cover, and wherein each pair of adjacent channels intersect with one another at an intersection.

6. The microelectronic device assembly of claim 1 wherein the non-planar surface feature includes a closed-loop channel in the peripheral portion.

7. The microelectronic device assembly of claim 1 wherein the non-planar surface feature includes a generally circular channel in the peripheral portion.

8. The microelectronic device assembly of claim 1 wherein the cover has a generally circular shape, and wherein the non-planar surface feature includes a generally circular channel in the peripheral portion, the channel being generally concentric with the cover.

9. An imager package, comprising:
an imager die having a plurality of photo sensors; and
an enclosure substantially enclosing the imager die, the enclosure having a cover attached to a base with an adhesive, the cover having a transparent central portion superimposed with the photo sensors of the imager die and a peripheral portion around the central portion, the cover having a non-planar portion in the peripheral portion, and wherein the non-planar portion is configured to increase a bonding strength between the cover and the base.

10. The imager package of claim 9 wherein a portion of the adhesive is in contact with the non-planar portion in the peripheral portion of the cover.

11. The imager package of claim 9 wherein the non-planar portion comprises a depression in the cover, and wherein a portion of the adhesive is in contact with the depression.

12. The imager package of claim 9 wherein the non-planar portion comprises a channel in the cover, and wherein a portion of the adhesive is in the channel.

13. The imager package of claim 9 wherein the non-planar portion comprises a plurality of channels in the cover, at least some of the channels being generally parallel to one another, and wherein a portion of the adhesive is in the plurality of channels.

14. The imager package of claim 9 wherein the non-planar portion comprises a channel on in the cover and a recess along an edge of the cover, and further wherein a portion of the adhesive is at least partially in the channel and the recess of the cover.

15. A process for forming a microelectronic imager package, comprising:
attaching a semiconductor die with a plurality of photo sensors to a base;
aligning a transparent portion of a cover with the photo sensors and a peripheral portion of the cover with the base, wherein the peripheral portion has a non-planar surface feature projecting into the cover;
disposing an adhesive onto at least one of the cover and the base; and
attaching the cover to the base such that the adhesive is at least partially in the non-planar surface feature.

16. The process of claim 15, further comprising forming the non-planar surface feature by scribing the cover with a dicing saw to form a channel and/or a recess.

17. The process of claim 15, further comprising forming the non-planar surface feature by scribing the cover with a dicing saw to form a generally linear channel having a generally rectangular cross section, a trapezoidal cross section, or a curved cross section.

18. The process of claim 15, further comprising forming the non-planar surface feature by scribing the cover with a dicing saw to form a channel having a closed-loop configuration.

19. The process of claim 15, further comprising forming the non-planar surface feature by scribing the cover with a dicing saw to form a generally circular channel having a generally rectangular cross section, a trapezoidal cross section, or a curved cross section.

20. The process of claim 15, further comprising forming the non-planar surface feature by scribing the cover with a dicing saw to form a channel and/or a recess, and wherein disposing an adhesive includes disposing the adhesive at least partially in the channel and/or recess.

21. The process of claim 15, further comprising forming the non-planar surface feature by scribing the cover with a dicing saw;
programming the dicing saw to form a channel on the surface of the cover; and
determining a depth of the channel based on a desired increase in contact surface area with the adhesive.

22. The process of claim 15, further comprising forming the non-planar surface feature by scribing the cover with a dicing saw;
programming the dicing saw to form a channel on the surface of the cover; and
selecting a blade for the dicing saw based on a desired cross-sectional profile of the channel.

23. An imager package, comprising:
an imager die having a plurality of photo sensors;
a base carrying the imager die;
a cover attached to the base with an adhesive, the cover having a transparent central superimposed with the photo sensors of the imager die and a peripheral portion around the central portion; and
means having a surface within the peripheral portion for increasing a bonding strength between the cover and the base.

24. The imager package of claim 23 wherein the means for increasing a bonding strength include means for increasing a contact surface area between the cover and the adhesive.

25. The imager package of claim 23 wherein the means for increasing a bonding strength include means for increasing a volume of the adhesive between the cover and the base.
